(19) United States
(12) Patent Application Publication
(10) Pub. No.: US 2025/0266625 A1
(43) Pub. Date: Aug. 21, 2025

(54) Bus Bar Structure

(71) Applicant: Yazaki Corporation, Tokyo (JP)

(72) Inventors: Hiroyuki Tanaka, Kakegawa-shi (JP); Takanori Kanamori, Kakegawa-shi (JP)

(21) Appl. No.: 19/199,918

(22) Filed: May 6, 2025

Related U.S. Application Data
(63) Continuation of application No. PCT/JP2023/043001, filed on Nov. 30, 2023.

(30) Foreign Application Priority Data
Dec. 7, 2022 (JP) 2022-195794

(51) Int. Cl. H01R 4/58; H01M 50/503; H01M 50/507; H01M 50/516; H01R 4/02

(52) U.S. Cl. CPC H01R 4/58; H01M 50/503; H01M 50/507; H01M 50/516; H01R 4/027; H01M 2220/20; H01R 2201/26

(57) ABSTRACT

This bus bar structure which is disposed on a disposition object surface is provided with a first conductive plate part having a first thickness and second conductive plate parts having a second thickness. The first thickness is thinner than the second thickness, the first conductive plate part and the second conductive plate parts continuously extend in the front-back direction, and the first conductive plate part is configured such that at least a part of a component protruding from the disposition object surface can be housed in the space between the first conductive plate part and the disposition object surface.

### CROSS-REFERENCE TO RELATED APPLICATIONS

This is a continuation of International Application No. PCT/JP2023/043001 filed on Nov. 30, 2023, and claims priority from Japanese Patent Application No. 2022-195794 filed on Dec. 7, 2022, the entire content of which is incorporated herein by reference.

### TECHNICAL FIELD

The present invention relates to a busbar structure.

### BACKGROUND ART

In a battery pack mounted on an electric automobile or a hybrid automobile that travels using an electric motor, a busbar is used for connecting electrodes of a plurality of cells. Further, even in an electric junction box for distributing power from a power source to various on-board devices in a vehicle, a busbar is also disposed inside to supply power to a predetermined load circuit (for example, refer to Patent Literature 1). When another component is present in a wiring path of a flat plate-shaped busbar and the busbar is wired across the other component, as shown in FIG. 3 of Patent Literature 1, the busbar is bent in part and routed so as to avoid the other component.

### CITATION LIST

### Patent Literature

Patent Literature 1: JP2000-151149A

### SUMMARY OF INVENTION

However, when the flat plate-shaped busbar is bent to straddle the other component, an extra space is required in a plate thickness direction, that is, in a height direction that is a direction away from a disposition object surface.

The present invention has been made in view of the above-described circumstances, and an object thereof is to provide a busbar structure capable of saving space in a height direction.

In order to achieve the object described above, the busbar structure according to the present invention is characterized as follows.

A busbar structure to be disposed on a disposition object surface, the busbar structure including:
a first conductive plate portion having a first thickness; and
a second conductive plate portion having a second thickness, in which
the first thickness is less than the second thickness,
the first conductive plate portion and the second conductive plate portion extend continuously in a first direction,
the first conductive plate portion is configured such that at least a part of a protrusion protruding from the disposition object surface is accommodated in a space between the first conductive plate portion and the disposition object surface,
the first conductive plate portion has a first end face extending in a second direction intersecting the first direction,
the second conductive plate portion has a second end face extending in the second direction,
the first conductive plate portion and the second conductive plate portion are joined to each other at the first end face and the second end face,
   wherein the first conductive plate portion has a first side face extending in a third direction intersecting the first end face,
the second conductive plate portion has a second side face extending in the third direction, and
the first conductive plate portion and the second conductive plate portion are joined to each other at the first side face and the second side face.

According to the present invention, it is possible to provide a busbar structure capable of saving space in a height direction.

The present invention has been briefly described above. Details of the present invention can be clarified by reading modes (hereinafter, referred to as “embodiments”) for carrying out the invention to be described below with reference to the accompanying drawings.

### BRIEF DESCRIPTION OF DRAWINGS

FIG. 1 is a perspective view showing a busbar structure according to a first embodiment;

FIG. 2 is an exploded perspective view of the busbar structure shown in FIG. 1;

FIG. 3 is a partially enlarged side view of the busbar structure shown in FIG. 1 in a wired state;

FIG. 4 is a perspective view showing a busbar structure according to a modification of the first embodiment;

FIG. 5 is a perspective view showing a busbar structure according to a second embodiment;

FIG. 6 is an exploded perspective view of the busbar structure shown in FIG. 5; and

FIG. 7 is a perspective view showing a busbar structure according to a modification of the second embodiment.

### DESCRIPTION OF EMBODIMENTS

Specific embodiments of the present invention will be described below with reference to the drawings.

### First Embodiment

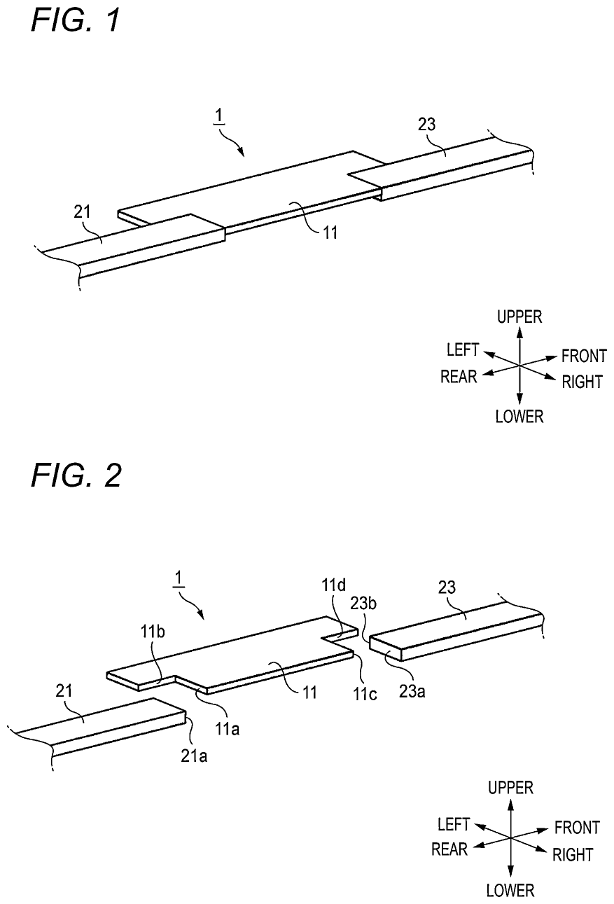

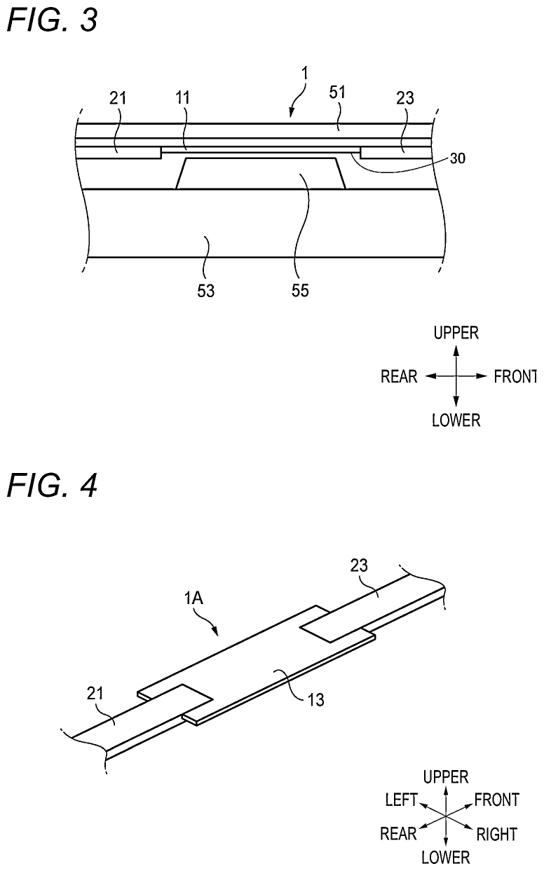

FIG. 1 is a perspective view showing a busbar structure 1 according to a first embodiment. FIG. 2 is an exploded perspective view of the busbar structure 1 shown in FIG. 1. FIG. 3 is a partially enlarged side view of the busbar structure 1 shown in FIG. 1 in a wired state. Hereinafter, for convenience of description, as shown in FIG. 1, a “front-rear direction”, a “left-right direction”, and an “upper-lower direction” are defined. The “front-rear direction”, the “left-right direction”, and the “upper-lower direction” are orthogonal to one another.

As shown in FIGS. 1 and 2, the busbar structure 1 is to be assembled between components and/or devices of an automobile and used for electrical connections within a battery pack that is used as a power supply to drive a motor of a vehicle, for example.

The busbar structure 1 is disposed on an upper face (see FIG. 3) of a component 53 as an example of a disposition object surface. The busbar structure 1 includes a busbar 11 having a first thickness and busbars 21 and 23 having a second thickness. The first thickness is less than the second thickness. The busbar 11 is an example of a first conductive plate portion, and the busbars 21 and 23 are an example of a second conductive plate portion. The busbar 11 and the busbars 21 and 23 extend in the front-rear direction. The front-rear direction is an example of a first direction. The busbar 11 is configured such that at least a part of a component 55 (see FIG. 3) can be accommodated in a space between the busbar 11 and the disposition object surface. The component 55 is an example of a protrusion protruding from the disposition object surface. The busbar structure 1 is a busbar for supplying vehicle driving power, that is, a high-voltage busbar.

The busbar 11 is formed by punching a conductive metal plate having a first thickness. The busbar 11 has a rectangular shape with front and rear right corners cut out into square shapes when viewed in the upper-lower direction. The busbar 11 includes end faces 11a and 11c extending in the left-right direction and side faces 11b and 11d extending in the front-rear direction. The left-right direction is an example of a second direction intersecting the first direction, and the end faces 11a and 11c are examples of a first end face. The side faces 11b and 11d are examples of a first side face. A dimension of the busbar 11 in the left-right direction is larger than a dimension of the busbars 21 and 23 in the left-right direction.

The busbars 21 and 23 are conductive metal plates having a second thickness, extending in the front-rear direction, and formed into a long, flat rectangular parallelepiped shape. The second thickness is less than a thickness (first thickness) of the busbar 11. The busbar 21 has an end face 21a extending in the left-right direction on a front side. The busbar 23 has an end face 23a extending in the left-right direction on a rear side. The end faces 21a and 23a are examples of a second end face.

Since the busbar 11 is thinner than the busbars 21 and 23, the busbar structure 1 can be disposed at a position where a space in the upper-lower direction, that is, a plate thickness direction is limited. In the related art, in a case where there is another component on a wiring path in the vehicle and the busbar is disposed to detour in a height direction (plate thickness direction) to avoid the other component, an extra space is required in the height direction, which is a direction away from the disposition object surface. However, since the busbar 11 is thinner than the busbars 21 and 23, a part of the other component can be accommodated in the space where the thickness is reduced. Accordingly, the busbar structure 1 can save the space in the height direction.

The busbar 11 and the busbar 21 are joined to each other by, for example, laser welding, with the end face 11a and the end face 21a abutting against each other. The end face 11c of the busbar 11 and the end face 23a and the busbar 23 are joined to each other by, for example, laser welding. By joining the busbar 11 and the busbars 21 and 23 having different thicknesses, the busbar structure 1 can be easily manufactured.

The busbar 11 and the busbar 21 are joined to each other at the side face 11b of the busbar 11 and a left side face of the busbar 21. The busbar 11 and the busbar 23 are joined to each other at the side face 11d of the busbar 11 and a side face 23b of the busbar 23. The busbar 11 and the busbars 21 and 23 are joined to each other in two directions, that is, the front-rear direction and the left-right direction, thereby enabling stable conduction.

The end face 11a and the side face 11b of the busbar 11 serve as joining faces with the busbar 21. A sum of the area of the end face 11a and the area of the side face 11b in the busbar 11, that is, the area of the joining faces with the busbar 21 is larger than the area of the end face 21a of the busbar 21. The end face 11c and the side face 11d of the busbar 11 serve as joining faces with the busbar 23. A sum of the area of the end face 11c and the area of the side face 11d in the busbar 11, that is, the area of the joining faces with the busbar 23 is larger than the area of the end face 23a of the busbar 23. In this way, since the area of the joining faces between the busbar 11 and the busbar 21, 23 is larger than the area of the cross section of the busbar 21, 23, that is, the area of the end face 21a, 23a, a current can be stably passed between the busbar 21 and the busbar 23.

In the busbar structure 1, the busbar 11 and the busbars 21 and 23 are joined such that upper faces thereof are flush with each other. An arrangement example of the busbar structure 1 is shown in FIG. 3. As shown in FIG. 3, the busbar structure 1 is disposed between a component 51 and the component 53. At this time, even when the component 55 is disposed to protrude upward from the upper face of the component 53, an upper portion of the component 55 can be accommodated in below the busbar 11 since the busbar 11 is thinner than the busbars 21 and 23. In other words, in the busbar structure 1, in a busbar in which the busbars 21, 11, and 23 are integrated, a recessed portion 30 formed by reducing the thickness (second thickness, a predetermined thickness) of the busbars 21 and 23 is provided on a lower face of the busbar 11, and the upper portion of the component 55 is accommodated in the recessed portion 30. Therefore, the busbar 11, which is thinner than other portions, is wired in a position where the space in the height direction is regulated, so that the busbar structure 1 can save space in the height direction. In addition, in the busbar structure 1, the busbar 11, which are thinner than the busbars 21 and 23, is used to secure the joining faces equal to or larger than the cross section area of the busbars 21 and 23, thereby enabling stable conduction. As described above, according to the busbar structure 1, it is possible to achieve both space saving in the height direction and stable conduction.

FIG. 4 is a perspective view showing a busbar structure 1A according to a modification of the first embodiment. In the busbar structure 1 according to the first embodiment described above, the thin busbar 11 is joined to the busbars 21 and 23 at the abutting surfaces (end faces 21a and 23a) and the left side face (side face 23b). In this regard, the busbar structure 1A shown 30 in FIG. 4 is different from the busbar 11 according to the first embodiment in the position of the notch provided in a busbar 13. The thin busbar 13 is joined to the busbars 21 and 23 also at a right side face in addition to the abutting surfaces and the left side face. In this manner, the thin busbar 13 may be joined to the busbars 21 and 23 in three directions. By joining in three directions, the area of joining faces between the busbar 13 and the busbars 21 and 23 can be increased, so that the conduction can be further stabilized.

### Second Embodiment

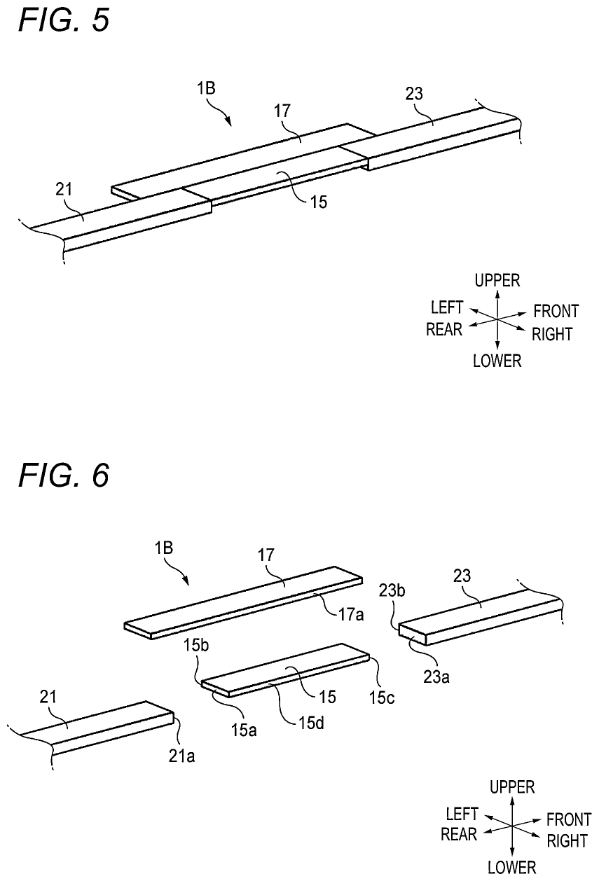

FIG. 5 is a perspective view showing a busbar structure 1B according to a second embodiment. FIG. 6 is an exploded perspective view of the busbar structure 1B shown in FIG. 5. Hereinafter, for convenience of description, as shown in FIG. 5, a “front-rear direction”, a “left-right direction”, and an “upper-lower direction” are defined. The “front-rear direction”, the “left-right direction”, and the “upper-lower direction” are orthogonal to one another. In the second embodiment, the same members and portions as those shown in FIGS. 1 to 4 are denoted by the same reference numerals, and redundant description thereof will be omitted.

As shown in FIGS. 5 and 6, the busbar structure 1B includes a busbar 15 having a first thickness, busbars 21 and 23 having a second thickness, and a busbar 17 having a third thickness less than the second thickness. The first thickness is less than the second thickness. The busbar 15 is an example of a first conductive plate portion, and the busbar 17 is an example of a third conductive plate portion. The busbar 15 and the busbar 17 extend in the front-rear direction. The front-rear direction is an example of a third direction.

The busbar 15 is a conductive metal plate having the first thickness, extending in the front-rear direction, and formed into a flat rectangular parallelepiped shape. The busbar 15 includes end faces 15a and 15c extending in the left-right direction and side faces 15b and 15d extending in the front-rear direction. The end faces 15a and 15c are examples of the first end face. The side face 15b is an example of the first side face.

The busbar 17 is a conductive metal plate having the third thickness, extending in the front-rear direction, and formed into a flat rectangular parallelepiped shape. The busbar 17 is formed longer than the busbar 15. In the present embodiment, the third thickness and the first thickness are the same thickness. The busbar 17 has a side face 17a extending in the front-rear direction. The side face 17a is an example of a third side face.

Since the busbars 15 and 17 are thinner than the busbars 21 and 23, the busbar structure 1B can be disposed at a position where a space in the upper-lower direction, that is, a height direction is limited. In the related art, in a case where there is another component on a wiring path in the vehicle and the busbar is disposed to detour in the height direction to avoid the other component, an extra space is required in the height direction. However, since the busbars 15, 17 are thinner than the busbars 21 and 23, a part of the other component can be accommodated in the space where the thickness is reduced. Accordingly, the busbar structure 1B can save the space in the height direction.

The busbar 15 and the busbar 21 are joined to each other by, for example, laser welding, with the end face 15a and the end face 21a abutting against each other. The end face 15c of the busbar 15 and the end face 23a and the busbar 23 are joined to each other by, for example, laser welding. By joining the busbars 15 and the busbars 21 and 23 having different thicknesses, the busbar structure 1B can be easily manufactured.

The busbar 15, the busbars 21 and 23, and the busbar 17 are configured such that the side face 15b of the busbar 15 and a central portion of the side face 17a of the busbar 17 are joined to each other, a front end portion of the left side face of the busbar 21 and a rear end portion of the busbar 17 are joined to each other, and a rear end portion of the side face 23b of the busbar 23 and a front end portion of the busbar 17 are joined to each other. In addition to the joining of the busbar 15 and the busbars 21 and 23 in the front-rear direction, the busbar 17 is also joined, so that more stable conduction is enabled by joining in two directions of the front-rear direction and the left-right direction.

The busbar 15 and the busbar 17 are joined to each other by the side faces 15b and 17a, so that functions the same as the busbar 11 shown in FIGS. 1 and 2 can be achieved as a single busbar.

The end face 15a of the busbar 15 and the rear end portion of the side face 17a of the busbar 17 serve as joining faces with the busbar 21. A sum of the area of the end face 15a of the busbar 15 and the area of the rear end portion of the side face 17a of the busbar 17 which is the area of a portion joined to the busbar 21, that is, the area of the joining faces with the busbar 21 is larger than the area of the end face 21a of the busbar 21. The end face 15c of the busbar 15 and the front end portion of the side face 17a of the busbar 17 serve as joining faces with the busbar 23. A sum of the area of the end face 11c of the busbar 15 and the area of the front end portion of the side face 17a of the busbar 17 which is the area of a portion joined to the busbar 23, that is, the area of the joining faces with the busbar 23 is larger than the area of the end face 23a of the busbar 23. In this way, since the area of the joining faces between the busbars 15 and 17 and the busbar 21, 23 is larger than the area of the cross section of the busbar 21, 23, that is, the area of the end face 21a, 23a, a current can be stably passed between the busbar 21 and the busbar 23.

In the busbar structure 1B, the busbars 15 and 17 and the busbars 21 and 23 are joined such that upper faces thereof are flush with each other. According to the busbar structure 1B, similarly to the busbar structure 1, it is possible to achieve both space saving in the height direction and stable conduction.

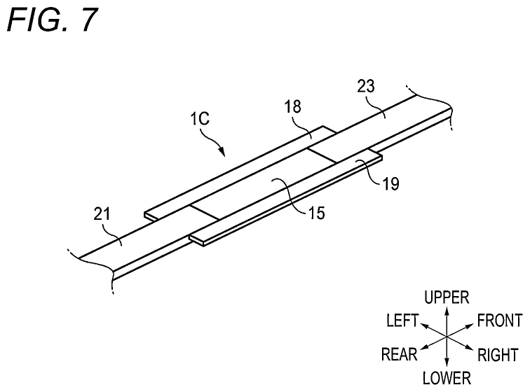

FIG. 7 is a perspective view showing a busbar structure 1C according to a modification of the second embodiment. In the busbar structure 1B according to the second embodiment described above, the thin busbars 15 and 17 are joined to the busbars 21 and 23 at the abutting surfaces (end faces 21a and 23a) and the left side face (side face 23b). In this regard, the busbar structure 1C shown in FIG. 7 differs from the busbar structure 1B in that busbars 18 and 19 are joined to left and right side faces of the busbar 15 instead of the busbar 17 joined to the left side face of the busbar 15. The busbars 18 and 19 have the same thickness as the busbars 15 and 17. The dimensions of the busbars 18 and 19 in the left-right direction are half the dimension of the busbar 17 in the left-right direction. The busbars 18 and 19 are an example of the third conductive plate portion. In this manner, the busbars 18 and 19 are separately joined to both side faces of the busbar 15, and the thin busbars 15, 18, and 19 integrally function similarly to the busbar 13 shown in FIG. 4. The busbar structure 1C is configured such that the thin busbars 15, 18, and 19 are joined to each of the busbars 21 and 23 in three directions, so that the area of joining faces between the thin busbars 15, 18, and 19 and the busbars 21 and 23 can be increased, and the conduction can be further stabilized.

The present invention is not limited to the above-described embodiments, and can be appropriately modified, improved, or the like. In addition, the material, shape, size, numerical value, form, number, arrangement position, and the like of components in the above-described embodiment are freely selected and are not limited as long as the present invention can be achieved. In the above-described embodiments, a busbar structure is manufactured by joining busbars having different thicknesses. Alternatively, the busbar structure may be manufactured by forming a part of a conductive plate having a uniform thickness into a thin shape by cutting or pressing.

Here, features of the busbar structure according to the embodiments of the present invention described above are briefly summarized and listed in the following [1] to [4].

[1] A busbar structure (1, 1A, 1B, and 1C) to be disposed on a disposition object surface (the upper face of the component 53), the busbar structure (1, 1A, 1B, and 1C) including:
a first conductive plate portion (busbars 11, 13, 15, 17, 18, and 19) having a first thickness; and
a second conductive plate portion (busbars 21 and 23) having a second thickness, in which
the first thickness is less than the second thickness,
the first conductive plate portion and the second conductive plate portion extend continuously in a first direction (front-rear direction),
the first conductive plate portion is configured such that at least a part of a protrusion (component 55) protruding from the disposition object surface is accommodated in a space between the first conductive plate portion and the disposition object surface,
the first conductive plate portion (11,13,15,17,18,19) has a first end face (11a, 11c, 15a, 15c) extending in a second direction intersecting the first direction,
   the second conductive plate portion (21,23) has a second end face (21a,23a) extending in the second direction,
   the first conductive plate portion (11,13,15,17,18,19) and the second conductive plate portion (21,23) are joined to each other at the first end face (11a, 11c, 15a, 15c) and the second end face (21a,23a),
the first conductive plate portion (11,13,15,17,18,19) has a first side face (11b,11d) extending in a third direction (front-rear direction) intersecting the first end face (11a, 11c, 15a, 15c),
   the second conductive plate portion (21,23) has a second side face (23b) extending in the third direction, and
the first conductive plate portion (11,13,15,17,18, 19) and the second conductive plate portion (21,23) are joined to each other at the first side face (11d) and the second side face (23b).

According to the busbar structure having the configuration of the above [1], the thickness of the first conductive plate portion is less than that of the second conductive plate portion, and at least a part of the protrusion can be accommodated in the space between the disposition object surface and the first conductive plate portion. Therefore, the busbar structure can be disposed at a position where a space in the height direction, that is, a thickness direction is limited. In the related art, in a case where there is another component on a wiring path in the vehicle and the busbar is disposed to detour in the height direction to avoid the other component, an extra space is required in the height direction. However, according to the above configuration, since the thickness of the first conductive plate portion is reduced, a protrusion such as a part of the other component can be accommodated in the space where the thickness is reduced. This makes it possible to save space in the height direction. Further, since the first conductive plate portion and the second conductive plate portion are also joined to the third conductive plate portion, stable conduction can be achieved.

[2] In the busbar structure (1B, 1C) according to [1], further including
a third conductive plate portion (17,18,19) having a third thickness less than the second thickness,
wherein the third conductive plate portion (17,18,19) has a third side face (17a) extending in the third direction, and
wherein the first conductive plate portion (11,13,15,17,18,19), the second conductive plate portion (21,23), and the third conductive plate portion (17,18,19) are joined to each other at the first side face (11b,11d), the second side face (23b), and the third side face (17a).

According to the busbar structure having the configuration of the above [2], the busbar structure can be easily manufactured by joining plates having different thicknesses. Further, since the first conductive plate portion and the second conductive plate portion are joined in two directions, the area of the joining face between the first conductive plate portion and the second conductive plate portion can be increased, so that stable conduction can be achieved.

[3] In the busbar structure (1, 1A, 1B, 1C) according to [2],
an area of a joining face between the first conductive plate portion and the second conductive plate portion is larger than an area of the second end face.

According to the busbar structure having the configuration of the above [3], the area of the joining face between the first conductive plate portion and the second conductive plate portion is larger than the area of the second end face of the second conductive plate portion. Therefore, an allowable current of the second conductive plate portion can be maintained in the first conductive plate portion.

[4] In the busbar structure (1, 1A, 1B, 1C) according to any one of [1] to [3],
the first conductive plate portion and the second conductive plate portion are busbars for supplying vehicle driving power.

According to the busbar structure having the configuration of the above [4], for example, it can be used for electrical connections within a battery pack that is used as a power supply to drive a motor of a vehicle.

The present application is based on a Japanese patent application (Japanese Patent Application No. 2022-195794) filed on Dec. 7, 2022, and the contents thereof are incorporated herein by reference.

### INDUSTRIAL APPLICABILITY

According to the present invention, it is possible to provide a busbar structure capable of saving space in a height direction. The present invention having this effect is useful in relation to a busbar structure.

What is claimed is:

1. A busbar structure to be disposed on a disposition object surface, the busbar structure comprising:
a first conductive plate portion having a first thickness; and
a second conductive plate portion having a second thickness,
wherein the first thickness is less than the second thickness,
wherein the first conductive plate portion and the second conductive plate portion extend continuously in a first direction,
wherein the first conductive plate portion is configured such that at least a part of a protrusion protruding from the disposition object surface is accommodated in a space between the first conductive plate portion and the disposition object surface,
wherein the first conductive plate portion has a first end face extending in a second direction intersecting the first direction,
wherein the second conductive plate portion has a second end face extending in the second direction,
wherein the first conductive plate portion and the second conductive plate portion are joined to each other at the first end face and the second end face,
wherein the first conductive plate portion has a first side face extending in a third direction intersecting the first end face,
wherein the second conductive plate portion has a second side face extending in the third direction, and
wherein the first conductive plate portion and the second conductive plate portion are joined to each other at the first side face and the second side face.

2. The busbar structure according to claim 1, further comprising:
a third conductive plate portion having a third thickness less than the second thickness,
wherein the third conductive plate portion has a third side face extending in the third direction, and
wherein the first conductive plate portion, the second conductive plate portion, and the third conductive plate portion are joined to each other at the first side face, the second side face, and the third side face.

3. The busbar structure according to claim 1,
wherein an area of a joining face between the first conductive plate portion and the second conductive plate portion is larger than an area of the second end face.

4. The busbar structure according to claim 1,
wherein the first conductive plate portion and the second conductive plate portion are busbars for supplying vehicle driving power.
